(19) United States
(12) Patent Application Publication
(10) Pub. No.: US 2022/0190647 A1
(43) Pub. Date: Jun. 16, 2022

(54) POWER TRANSMITTING DEVICE AND WIRELESS POWER TRANSMISSION SYSTEM

(71) Applicant: PANASONIC INTELLECTUAL PROPERTY MANAGEMENT CO., LTD., Osaka (JP)

(72) Inventors: Hiroyuki HOSOI, Kanagawa (JP); Hiroshi YAMAMOTO, Osaka (JP)

(21) Appl. No.: 17/598,337

(22) PCT Filed: Mar. 26, 2020
(86) PCT No.: PCT/JP2020/013807

§ 371 Date: Sep. 27, 2021

(30) Foreign Application Priority Data
Mar. 29, 2019 (JP) 2019-067875

(51) Int. Cl. H02J 50/12; H02J 50/40; H02J 50/70; H02M 7/48

(52) U.S. Cl. CPC H02J 50/12; H02M 7/4818; H02J 50/70; H02J 50/40

(57) ABSTRACT

A power transmitting device includes: an inverter circuit; a power transmitting antenna connected to the inverter circuit, and being electromagnetically coupled to a power receiving antenna in a power receiving device to wirelessly transmit electric power thereto; a detector to detect an output voltage and an output current of the inverter circuit; and a control circuit to control the inverter circuit. The control circuit consecutively drives the inverter circuit at a plurality of frequencies, determines from among the plurality of frequencies a frequency at which a phase difference that is indicative of a lag of a phase of the output current relative to a phase of the output voltage becomes largest, and performs power transmission by driving the inverter circuit at an operating frequency that is based on the determined frequency.

### TECHNICAL FIELD

The present disclosure relates to a power transmitting device and a wireless power transmission system.

### BACKGROUND ART

Recent years have seen development of wireless power transmission techniques for wirelessly (contactlessly) transmitting electric power to devices that are capable of moving or being moved, e.g., mobile phones and electric vehicles. Wireless power transmission techniques include the magnetic field coupling method, the electric field coupling method, and other methods. A wireless power transmission system based on the electromagnetic induction method is such that, while a power transmitting coil and a power receiving coil are opposed to each other, electric power is wirelessly transmitted from the power transmitting coil to the power receiving coil. On the other hand, a wireless power transmission system based on the electric field coupling method is such that, while a pair of transmission electrodes and a pair of reception electrodes are opposed to each other, electric power is wirelessly transmitted from the pair of transmission electrodes to the pair of reception electrodes.

Patent Document 1 discloses an example of a system in which electric power is contactlessly transmitted between a power transmitting device that includes a power transmitting coil and a power receiving device that includes a power receiving coil. The power transmitting device in Patent Document 1 includes an inverter, a power transmitting section, and a control means. The inverter includes a plurality of switching elements and a plurality of diodes. The power transmitting section transmits AC power from the inverter to the power receiving device. The control means controls the plurality of switching elements in the inverter. Upon detecting that the output current from the inverter is more advanced in phase than the output voltage, the control means adjusts the frequency so that the angle of phase advance of the current becomes smaller. As a result of this, hard switching of the switching elements can be avoided, whereby abnormal heating and malfunctioning of the switching elements of the power transmitting device can be suppressed.

Patent Document 2 discloses a power transmitting device that includes a power transmitting coil, a power transmitting circuit, a phase detection circuit, and a control circuit. The power transmitting circuit includes an inverter, and supplies electric power to the power transmitting coil based on the output power of a DC source. The phase detection circuit detects the phase of the output current of the inverter. In accordance with the result of detection by the phase detection circuit, the control circuit controls the DC source. Specifically, by varying the output voltage of the DC source, the control circuit brings the phase of the output current of the inverter as detected by the phase detection circuit closer to a predetermined target value. It is stated that this can suppress degradations of the power efficiency when the interspace between the power transmitting coil and the power receiving coil increases.

### CITATION LIST

### Patent Literature

[Patent Document 1] Japanese Laid-Open Patent Publication No. 2016-111902

[Patent Document 2] Japanese Laid-Open Patent Publication No. 2013-153627

### SUMMARY OF INVENTION

### Technical Problem

The present disclosure provides a technique of suppressing degradation of the efficiency of power transmission associated with changes in the state of wireless power transmission.

### Solution to Problem

A power transmitting device according to one implementation of the present disclosure is for use in a wireless power transmission system that includes the power transmitting device and a power receiving device. The power transmitting device comprises: an inverter circuit; a power transmitting antenna connected to the inverter circuit; a detector to detect an output voltage and an output current of the inverter circuit; and a control circuit to control the inverter circuit. The power transmitting antenna is electromagnetically coupled to a power receiving antenna in the power receiving device to wirelessly transmit electric power thereto. The power transmitting circuit consecutively drives the inverter circuit at a plurality of frequencies; determines from among the plurality of frequencies a frequency at which a phase difference that is indicative of a lag of a phase of the output current relative to a phase of the output voltage becomes largest; and performs power transmission by driving the inverter circuit at an operating frequency that is based on the determined frequency.

General or specific aspects of the present disclosure may be implemented using a system, an apparatus, a method, an integrated circuit, a computer program, or a storage medium, or any combination of a system, an apparatus, a method, an integrated circuit, a computer program, and/or a storage medium.

### Advantageous Effects of Invention

According to a technique of the present disclosure, degradation of the efficiency of power transmission associated with changes in the state of wireless power transmission can be suppressed.

### BRIEF DESCRIPTION OF DRAWINGS

FIG. 1 A diagram showing schematically showing an example of a wireless power transmission system based on the electric field coupling method.

FIG. 2 A diagram showing a general configuration of the wireless power transmission system shown in FIG. 1.

FIG. 3 A diagram schematically showing another example of a wireless power transmission system based on the electric field coupling method.

FIG. 4 A diagram showing a general configuration of the wireless power transmission system shown in FIG. 3.

FIG. 5 A diagram schematically showing example waveforms of an output voltage and an output current of an inverter circuit.

FIG. 6 A diagram showing an exemplary configuration of a power transmitting circuit and a power receiving circuit.

FIG. 7A A graph showing an example frequency dependence of the phase difference between an output voltage and an output current of an inverter circuit.

FIG. 7B A graph showing an example relationship between the efficiency of wireless power transmission and the phase difference.

FIG. 8 A block diagram showing the configuration of a wireless power transmission system according to an illustrative embodiment of the present disclosure.

FIG. 9 A diagram showing a more specific exemplary configuration of a power transmitting circuit and a power receiving circuit.

FIG. 10A A diagram schematically showing an exemplary configuration of an inverter circuit.

FIG. 10B A diagram schematically showing an exemplary configuration of a rectifier circuit.

FIG. 11 A diagram showing an exemplary configuration of a charge-discharge control circuit.

FIG. 12 A diagram showing one example of the circuit configuration of a DC-DC converter.

FIG. 13 A diagram showing an exemplary configuration of a detector and a power transmission control circuit.

FIG. 14 A flowchart showing an example operation of a power transmitting device.

FIG. 15 A flowchart showing another example operation of the power transmitting device.

FIG. 16A A diagram showing an example where the transmission electrodes are installed on a lateral surface e.g., a wall.

FIG. 16B A diagram showing an example where the transmission electrodes are installed on a ceiling.

FIG. 17 A diagram showing an example system in which electric power is wirelessly transmitted through coupling between coils.

### DESCRIPTION OF EMBODIMENTS

(findings providing the basis of the present disclosure)

Prior to describing embodiments of the present disclosure, findings providing the basis of the present disclosure will be described.

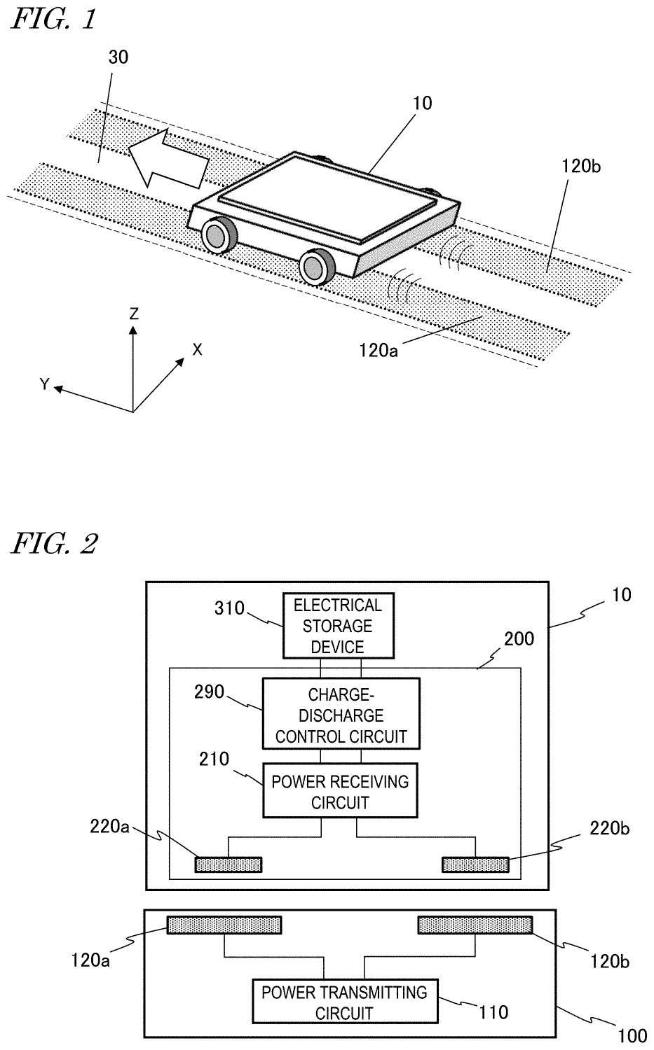

FIG. 1 is a diagram schematically showing an example of a wireless power transmission system. The wireless power transmission system shown in the figure may be a system which wirelessly transmits electric power, through electric field coupling between electrodes, to a movable unit 10 that is used in transporting articles in a factory or a warehouse, for example. The movable unit 10 in this example is an automated guided vehicle (AGV). In this system, a pair of transmission electrodes 120a and 120b, which are in plate shape, are disposed on the floor surface 30. The pair of transmission electrodes 120a and 120b have a shape that is elongated in one direction. To the pair of transmission electrodes 120a and 120b, AC power is supplied from a power transmitting circuit not shown.

The movable unit 10 includes a pair of reception electrodes (not shown) opposing the pair of transmission electrodes 120a and 120b. With the pair of reception electrodes, the movable unit 10 receives AC power which has been transmitted from the transmission electrodes 120a and 120b. The received electric power is supplied to a load in the movable unit 10, e.g., a motor, a secondary battery, or a capacitor for electrical storage purposes. With this, the movable unit 10 may be driven or charged.

FIG. 1 shows XYZ coordinates indicating the X, Y and Z directions which are orthogonal to one another. The following description will rely on XYZ coordinates as shown in the figures. The direction that the transmission electrodes 120a and 120b extend will be referred to as the Y direction; a direction which is perpendicular to the surface of the transmission electrodes 120a and 120b as the Z direction; and a direction which is perpendicular to the Y direction and the Z direction as the X direction. Note that the orientation of any structure that is shown in a drawing of the present application is so set for ease of description, and it shall not limit the orientation in which an embodiment of the present disclosure may actually be employed. Moreover, the particular shape and size with which the whole or a part of any structure may be presented in a drawing shall not limit its actual shape and size.

FIG. 2 is a diagram showing the general configuration of the wireless power transmission system shown in FIG. 1. The wireless power transmission system includes a power transmitting device 100 and a movable unit 10. The power transmitting device 100 includes a pair of transmission electrodes 120a and 120b, and a power transmitting circuit 110 which supplies AC power to the transmission electrodes 120a and 120b. The power transmitting circuit 110 is, for example, an AC output circuit including an inverter circuit. The power transmitting circuit 110 converts DC power which is supplied from a power source not shown into AC power, and outputs it to the pair of transmission electrodes 120a and 120b. The movable unit 10 includes a power receiving device 200 and an electrical storage device 310. The power receiving device 200 includes a pair of reception electrodes 220a and 220b, a power receiving circuit 210, and a charge-discharge control circuit 290. The electrical storage device 310 is a device that stores electric power, e.g., a motor, a capacitor for electrical storage purposes, or a secondary battery. The power receiving circuit 210 converts the AC power received by the reception electrodes 220a and 220b into a voltage required by the electrical storage device 310, e.g., a DC power of a predetermined voltage level, and outputs it. The power receiving circuit 210 may include various circuits, e.g., a rectifier circuit and an impedance matching circuit. The charge-discharge control circuit 290 is a circuit that controls charging and discharging of the electrical storage device 310. Although not shown in FIG. 2, the movable unit 10 also includes other loads, such as electric motors for driving purposes. Through electric field coupling between the pair of transmission electrodes 120a and 120b and the pair of reception electrodes 220a and 220b, electric power is wirelessly transmitted while the two pairs are opposed to each other.

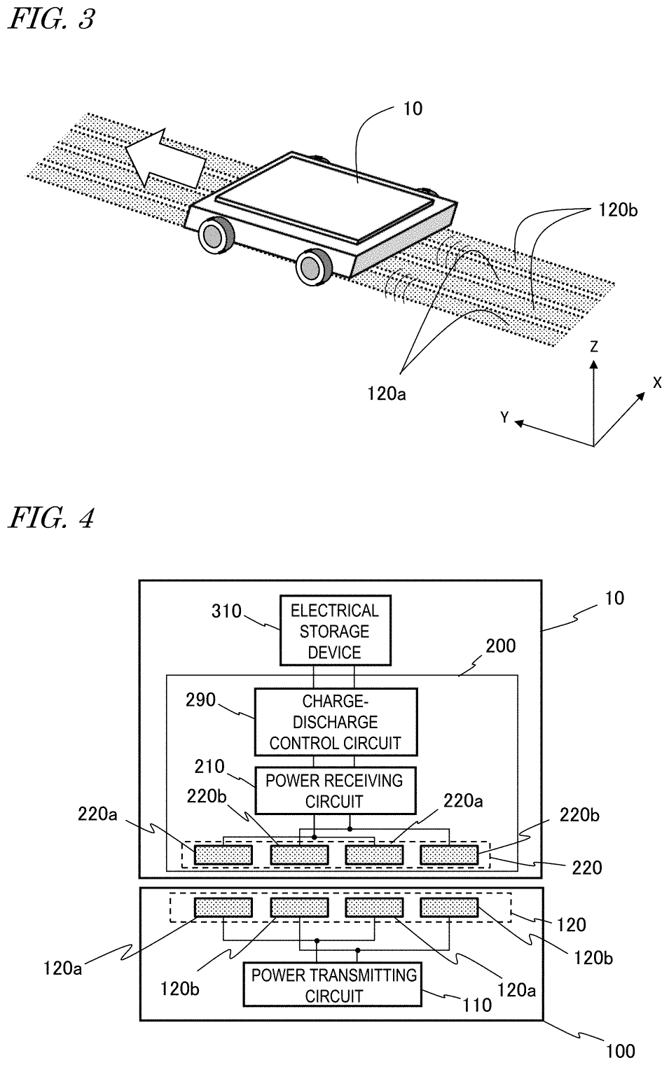

Each of the transmission electrodes 120a and 120b and the reception electrodes 220a and 220b may be split into two or more portions. For example, a configuration as shown in FIG. 3 and FIG. 4 may be adopted.

FIG. 3 and FIG. 4 are diagrams showing an example of a wireless power transmission system in which each of the transmission electrodes 120a and 120b and the reception electrodes 220a and 220b is split into two portions. In this example, the power transmitting device 100 includes two first transmission electrodes 120a and two second transmission electrodes 120b. The first transmission electrodes 120a and the second transmission electrodes 120b are arranged in an alternating manner. Similarly, the power receiving device 200 includes two first reception electrodes 220a and two second reception electrodes 220b. The two first reception electrodes 220a and the two second reception electrodes 220b are arranged in an alternating manner. During power transmission, the two first reception electrodes 220a are opposed to the two first transmission electrodes 120a, and the two second reception electrodes 220b are opposed to the two second transmission electrodes 120b. The power transmitting circuit 110 includes two terminals to output AC power. One terminal is connected to the two first transmission electrodes 120a, whereas the other terminal is connected to the two second transmission electrodes 120b. During power transmission, the power transmitting circuit 110 applies a first voltage to the two first transmission electrodes 120a, and applies a second voltage of an opposite phase to the first voltage to the two second transmission electrodes 120b. As a result of this, through electric field coupling between the transmission electrode group 120 including four transmission electrodes and the reception electrode group 220 including four reception electrodes, electric power is wirelessly transmitted. Such a configuration provides an effect of suppressing a leakage field at a boundary between any two adjacent transmission electrodes. Thus, in each of the power transmitting device 100 and the power receiving device 200, the number of electrodes with which to perform power transmission or power reception is not limited to two.

In the following embodiments, as shown in FIG. 1 and FIG. 2, a configuration in which the power transmitting device 100 includes two transmission electrodes and the power receiving device 200 includes two reception electrodes will be mainly described. In each of the following embodiments, each electrode may be split into multiple portions as illustrated in FIG. 3 and FIG. 4. In either case, an electrode(s) to which a first voltage is applied at a given moment and an electrode(s) to which a second voltage of an opposite phase to the first voltage is applied are arranged in an alternating manner. As used herein, an “opposite phase” is defined to encompass a phase difference which is anywhere in the range from 90 degrees to 270 degrees, without being limited to the case where the phase difference is 180 degrees. In the following description, a plurality of transmission electrodes included in the power transmitting device 100 may be non-discriminately referred to as “transmission electrodes 120” and a plurality of reception electrodes included in the power receiving device 200 may be non-discriminately referred to as “reception electrodes 220”.

With such a wireless power transmission system, the movable unit 10 is able to wirelessly receive electric power while moving along the transmission electrodes 120. While the transmission electrodes 120 and the reception electrodes 220 remain in a closely opposed state, the movable unit 10 is able to move along the transmission electrodes 120. As a result, the movable unit 10 is able to move while charging the electrical storage device 310, e.g., a battery or a capacitor.

In such a wireless power transmission system, when the weight of the load carried on the movable unit 10 is changed, or the course of the movable unit 10 deviates from the direction that the transmission electrodes 120 extend, a capacitance between the electrodes may change from the design value. When such a fluctuation in the capacitance between the electrodes or a fluctuation in the load state occurs, a mismatch in impedance between circuits, or hard switching in the inverter circuit may occur. In that case, problems such as degradation of the efficiency of power transmission or heating or damaging of circuit elements may occur.

This problem may occur not only in a wireless power transmission system based on the electric field coupling method, but also in a wireless power transmission system based on the magnetic field coupling method. In other words, because of fluctuations in the coupling state between the coils or fluctuations in the load state, problems such as degradation of the efficiency of power transmission or heating or damaging of circuit elements may occur.

The inventors have studied control methods for solving the above problems, and arrived at the configurations of embodiments of the present disclosure described below. Hereinafter, the embodiments of the present disclosure will be described in outline.

A power transmitting device according to one implementation of the present disclosure is for use in a wireless power transmission system that includes the power transmitting device and a power receiving device, the power transmitting device. The power transmitting device includes: an inverter circuit; a power transmitting antenna; a detector; and a control circuit to control the inverter circuit. The power transmitting antenna is connected to the inverter circuit, and electromagnetically coupled to a power receiving antenna in the power receiving device to wirelessly transmit electric power thereto. The detector detects an output voltage and an output current of the inverter circuit. The control circuit consecutively drives the inverter circuit at a plurality of frequencies; determines from among the plurality of frequencies a frequency at which a phase difference that is indicative of a lag of a phase of the output current relative to a phase of the output voltage becomes largest; and performs power transmission by driving the inverter circuit at an operating frequency that is based on the determined frequency.

With the above configuration, the control circuit consecutively drives the inverter circuit at a plurality of frequencies; determines from among the plurality of frequencies a frequency at which a phase difference that is indicative of a lag of a phase of the output current relative to a phase of the output voltage becomes largest; and performs power transmission by driving the inverter circuit at an operating frequency that is based on the determined frequency. This allows for suppressing a degradation of the efficiency of power transmission to occur in the presence of a fluctuation in the coupling state between the power transmitting antenna and the power receiving antenna, or in the presence of a load fluctuation. As a result, heating or damaging of circuit elements can be suppressed.

From among the plurality of frequencies, the control circuit may determine the frequency at which the phase difference becomes largest as the operating frequency. Alternatively, the control circuit may determine as the operating frequency any other frequency that is determined based on the frequency at which the phase difference becomes largest. Thus, the “operating frequency based on the determined frequency” may be identical to the determined frequency, or differ from the frequency so long as similar action and effects are obtained.

In a typical embodiment, the control circuit performs the above operation of determining the operating frequency when beginning power transmission. The control circuit may perform the above operation during power transmission.

Now, with reference to FIG. 5, the significance of “phase difference” in the present disclosure will be described. FIG. 5 is a diagram schematically showing an example of waveforms over time of an output voltage Vsw and an output current Ires of an inverter circuit. A phase difference £p represents a lag of the phase of the output current Ires relative to the phase of the output voltage Vsw. Now, assume a value Lt obtained by subtracting a point in time when the value of the output voltage Vsw changes from positive to negative from a point in time when the value of the output current Ires changes from positive to negative. Given a frequency f, the phase difference Δφ is expressed as Δφ=2πfΔt. Since the phase difference Δφ is in proportion to the time difference Δt, the time difference Δt may be referred to as a “phase difference” in the following description. The phase difference Δφ takes a positive value when the phase of the output current Ires is lagged behind the phase of the output voltage Vsw, i.e., slower-phased, and takes a negative value when the phase of the output current is ahead of the phase of the output voltage, i.e., faster-phased. Therefore, when the phase difference is positive, the control circuit determines an operating frequency such that the phase difference has a larger absolute value; when the phase difference is negative, the control circuit determines an operating frequency such that the phase difference has a smaller absolute value, i.e., closer to zero.

In the present disclosure, an “antenna” is an element which wirelessly transmits power or receives power through electromagnetic coupling. An antenna may encompass, e.g., a coil, or two or more electrodes.

A wireless power transmission system according to an embodiment of the present disclosure includes the above power transmitting device and a power receiving device. The wireless power transmission system performs wireless power transmission by an electric field coupling method or a magnetic field coupling method, for example. The “electric field coupling method” refers to a method which wirelessly transmits electric power through electric field coupling between two or more transmission electrodes and two or more reception electrodes. The “magnetic field coupling method” refers to a method which wirelessly transmits electric power through magnetic field coupling between a power transmitting coil and a power receiving coil. In a wireless power transmission system based on the electric field coupling method, a power transmitting antenna includes two or more transmission electrodes, whereas a power receiving antenna includes two or more reception electrodes. In a wireless power transmission system based on the magnetic field coupling method, a power transmitting antenna includes a power transmitting coil, whereas a power receiving antenna includes a power receiving coil. Although the present specification will mainly describe wireless power transmission systems based on the electric field coupling method, the configuration of each embodiment of the present disclosure is similarly applicable to a wireless power transmission system based on the magnetic field coupling method.

The technique of the present disclosure is based on the finding by the inventors that even if the coupling state between a power transmitting antenna and a power receiving antenna or the load state changes, degradation of the efficiency of power transmission can be suppressed by controlling the frequencies so as to result in a large phase difference. Hereinafter, this point will be described.

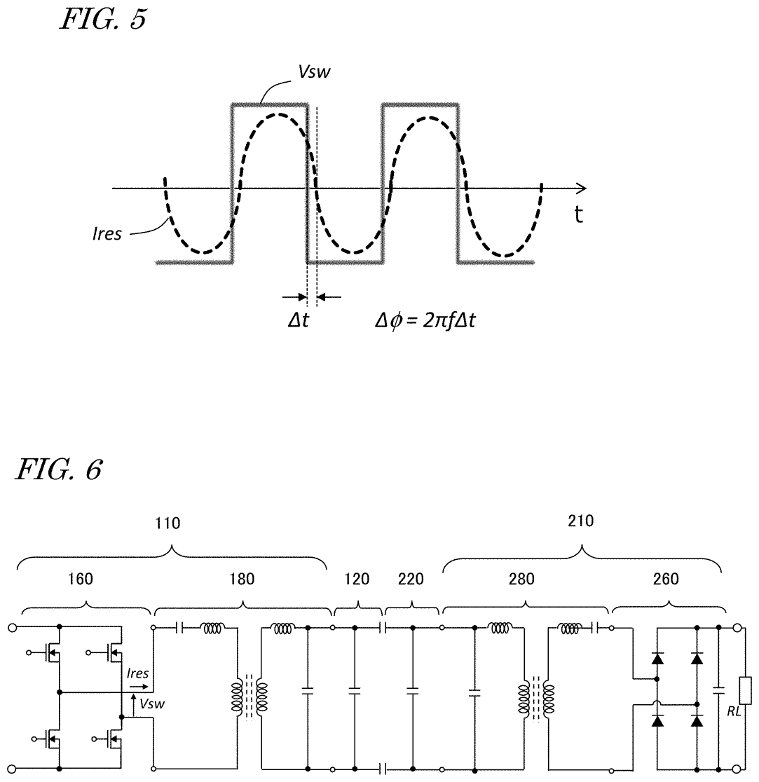

FIG. 6 is a diagram showing the circuit configuration of the power transmitting circuit 110, the transmission electrodes 120, the reception electrodes 220, and the power receiving circuit 210 in an illustrative wireless power transmission system. The power transmitting circuit 110 in this example includes an inverter circuit 160 and a matching circuit 180. The power receiving circuit 210 includes a matching circuit 280 and a rectifier circuit 260. The matching circuit 180, which is connected between the inverter circuit 160 and the transmission electrodes 120, matches the inverter circuit 160 and the transmission electrodes 120 in impedance. The matching circuit 280, which is connected between the reception electrodes 220 and a rectifier circuit 260, matches the reception electrodes 220 and the rectifier circuit 260 in impedance.

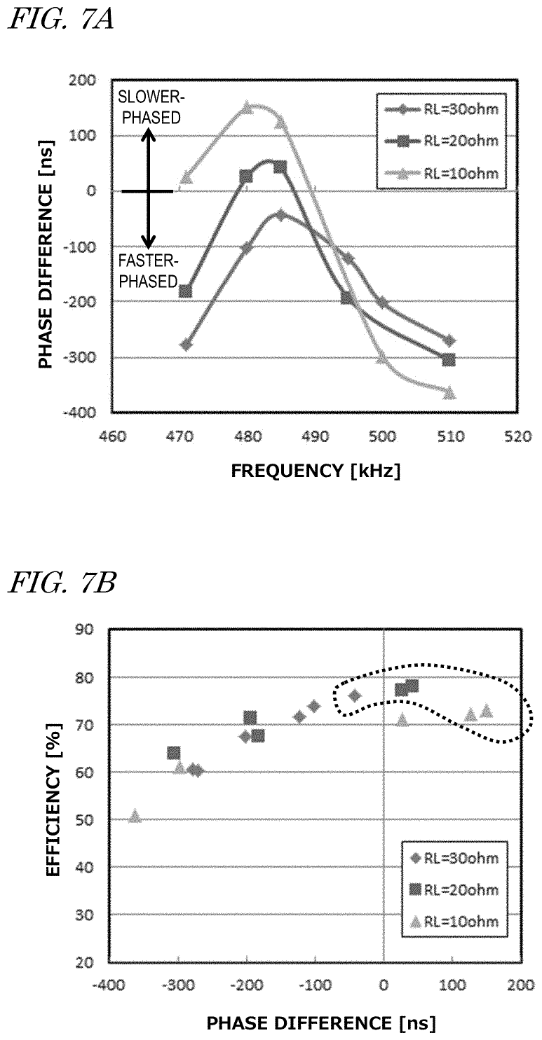

FIG. 7A and FIG. 7B are diagrams showing results of an experiment performed by the inventors with respect to the configuration shown in FIG. 6. In this experiment, with respect to the configuration shown in FIG. 6, the parameters of each circuit element were set to appropriate values, and, while varying the driving frequency of the inverter circuit 160, a phase difference between the output voltage Vsw and the output current Ires and an efficiency of power transmission were calculated for each frequency. The experiment was conducted for the case where the load was RL=20Ω, which was the design value, as well as the case where RL=10Ω and the case where RL=30Ω, which were deviated from the design value.

FIG. 7A shows an example relationship between the frequency and the phase difference. FIG. 7B shows an example relationship between the phase difference and the efficiency of power transmission. As shown in FIG. 7A, as the load state changes, frequency dependence of the phase difference also changes. The phase difference becomes largest at a certain frequency that is determined depending on the load value. As shown in FIG. 7B, under any load condition, the efficiency of power transmission tends to improve as the phase difference becomes larger.

From this result, it was found that, even if the coupling state between the antennas or the load state changes, it is still possible to maintain a high efficiency by controlling the driving frequency of the inverter circuit 160 so that the phase difference is kept near its maximum value (e.g., as indicated by a broken-lined frame in FIG. 7B). Under such control, when faster-phased, the faster-phased state can be at least somewhat improved to reduce losses associated with hard switching. When slower-phased, too, the matching state is improved, whereby the efficiency can be improved. As a result, heating or break down of circuit elements can be prevented.

The power transmitting device may further include an adjustment circuit to adjust the voltage to be input to the inverter circuit. The control circuit may control the adjustment circuit to perform an operation of determining the operating frequency with an electric power which is lower than that in a power transmission operation occurring after the operating frequency has been determined.

With the above configuration, the operation for determining the operating frequency is performed with an electric power which is lower than that in a power transmission operation occurring after the operating frequency has been determined. As a result, even if an impedance mismatch or hard switching ascribable to the operation for determining the operating frequency occurs, damage to the circuit elements can be reduced. In the following description, the operation for determining the operating frequency may be referred to as “preliminary power transmission”, whereas the power transmission operation after the operating frequency is determined may be referred to as “main power transmission”.

The electric power during the preliminary power transmission may be set to less than 1/10 of the electric power during the main power transmission. In one example, the electric power during the preliminary power transmission may be set to less than 1/100 of the electric power during the main power transmission. For instance, when the rated power during the main power transmission is 1 kW, the electric power during the preliminary power transmission may be set to several W to several tens of W, for example.

The adjustment circuit may be a DC-DC converter circuit connected between the inverter circuit and an external DC power source, or an AC-DC converter circuit connected between an external AC power source and the inverter circuit. The control circuit is able to adjust the voltage to be input to the inverter circuit by controlling the duty ratio of a control signal to be input to a switching element in the DC-DC converter or AC-DC converter circuit. This allows the electric power during the preliminary power transmission to be smaller than the electric power during the main power transmission.

The plurality of frequencies used during the preliminary power transmission may include three or more frequencies, for example. In one example, preliminary power transmissions may be performed at five or more frequencies. The more frequencies there are, the higher the possibility of being able to determine a more preferable operating frequency will be, but the longer the time required for the preliminary power transmission will be. The plural number of frequencies to be used for the preliminary power transmission is set appropriate in accordance with the permissible time before the main power transmission is begun.

The control circuit may use the hill-climbing method to determine the frequency at which the phase difference becomes largest, for example. In this case, the control circuit gradually increases or decreases the frequency within a certain frequency range, each time calculates a phase difference, and determines a frequency at which the phase difference takes a local maximum, or a frequency in that neighborhood, as the operating frequency.

The control circuit performs the operation of determining the operating frequency in an amount of time shorter than 1 second, for example. In one example, this operation may be performed within 100 milliseconds, for example. By determining the operating frequency in such a short time, a delay in beginning power transmission associated with the operating frequency can be suppressed.

The power transmitting device may further include an impedance matching circuit connected between the inverter circuit and the power transmitting antenna. The detector may detect a voltage and a current between the inverter circuit and the impedance matching circuit, or inside the impedance matching circuit, respectively as the output voltage and the output current.

The wireless power transmission system may include a movable unit that includes the power receiving device. The movable unit may include an electric motor that is driven with energy which is stored in an electrical storage device. The movable unit may further include an electrical storage device such as a secondary battery or a capacitor.

The movable unit is not limited to a vehicle such as the aforementioned AGV, but encompasses any movable object that is driven by electric power. Examples of movable units may include an electric vehicle that includes an electric motor and one or more wheels. Such a vehicle may be the aforementioned AGV, an electric vehicle (EV), or an electric cart, for example. The “movable unit” within the meaning of the present disclosure also encompasses any movable object that lacks wheels. For example, bipedal robots, unmanned aerial vehicles (UAV, or so-called drones) such as multicopters, and manned electric aircraft are also encompassed within “movable units”.

Hereinafter, more specific embodiments of the present disclosure will be described. Note however that unnecessarily detailed descriptions may be omitted. For example, detailed descriptions on what is well known in the art or redundant descriptions on what is substantially the same configuration may be omitted. This is to avoid lengthy description, and facilitate the understanding of those skilled in the art. The accompanying drawings and the following description, which are provided by the present inventors so that those skilled in the art can sufficiently understand the present disclosure, are not intended to limit the scope of claims. In the following description, identical or similar constituent elements are denoted by identical reference numerals.

### EMBODIMENTS

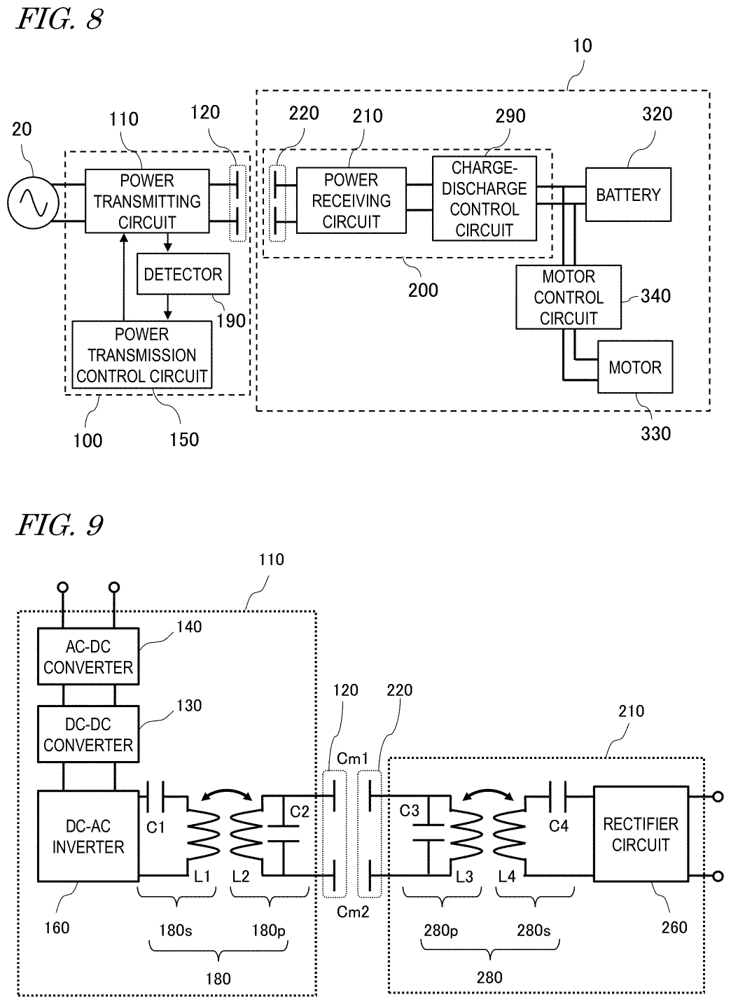

FIG. 8 is a block diagram showing the configuration of a wireless power transmission system according to an illustrative embodiment of the present disclosure. The wireless power transmission system includes a power transmitting device 100 and a movable unit 10. The movable unit 10 includes a power receiving device 200, a secondary battery 320 which is an electrical storage device, an electric motor 330 for driving purposes, and a motor control circuit 340. FIG. 8 also shows a power source 20, which is an external element to the wireless power transmission system. Hereinafter, the secondary battery 320 may simply be referred to as the “battery 320”, and the electric motor 330 for driving purposes may simply be referred to as the “motor 330”.

The power transmitting device 100 includes two transmission electrodes 120, a power transmitting circuit 110 to supply AC power to the two transmission electrodes 120, a detector 190, and a power transmission control circuit 150. The detector 190 detects a voltage and a current in the power transmitting circuit 110. Based on an output from the detector 190, the power transmission control circuit 150 controls the power transmitting circuit 110.

The power receiving device 200 includes two reception electrodes 220, a power receiving circuit 210, and a charge-discharge control circuit 290. While respectively being opposed to the two transmission electrodes 120, the two reception electrodes 220 receive AC power from the transmission electrodes 120 through electric field coupling. The power receiving circuit 210 converts the AC power received by the reception electrodes 220 into DC power, and outputs it. The charge-discharge control circuit 290 monitors the charge state of the secondary battery 320, and controls charging and discharging. The charge-discharge control circuit 290 is also referred to as a battery management unit (BMU). The charge-discharge control circuit 290 also has the function of protecting cells in the secondary battery 320 from overcharging, overdischarging, overcurrent, high temperature, low temperature, or other states.

Hereinafter, the respective component elements will be described more specifically.

The power source 20 may be an AC power source for commercial use, for example. The power source 20 outputs an AC power with a voltage of 100 V and a frequency of 50 Hz or 60 Hz, for example. The power transmitting circuit 110 converts the AC power supplied from the power source 20 into an AC power of a higher voltage and a higher frequency, and supplies it to the pair of transmission electrodes 120.

The secondary battery 320 is a rechargeable battery, such as a lithium-ion battery or a nickel-metal hydride battery. The movable unit 10 is able to move by driving the motor 330 with the electric power stored in the secondary battery 320. Instead of the secondary battery 320, a capacitor for electrical storage purposes may be used. For example, a high-capacitance and low-resistance capacitor, such as an electric double layer capacitor or a lithium-ion capacitor, may be used.

When the movable unit 10 moves, the amount of stored electricity in the secondary battery 320 becomes lower. Therefore, recharging will be required in order to continue moving. Therefore, when the charged amount becomes smaller than a predetermined threshold value during movement, the movable unit 10 moves to the power transmitting device 100 to perform charging.

The motor 330 may be any type of motor, such as a permanent magnet synchronous motor, an induction motor, a stepping motor, a reluctance motor, or a DC motor. The motor 330 rotates wheels of the movable unit 10 via a transmission mechanism, e.g., shafts and gears, thus causing the movable unit 10 to move.

The motor control circuit 340 controls the motor 330 to cause the movable unit 10 to perform a desired operation. The motor control circuit 340 may include various circuits, such as an inverter circuit, that are designed in accordance with the type of the motor 330.

Although not particularly limited, the respective sizes of the housing of the movable unit 10 according to the present embodiment, the transmission electrodes 120, and the reception electrodes 220 may be set to the following sizes, for example. The length (i.e., the size along the Y direction) of each transmission electrode 120 may be set in a range from 50 cm to 20 m, for example. The width (i.e., the size along the X direction) of each transmission electrode 120 may be set in a range from 5 cm to 2 m, for example. The sizes along the traveling direction and the lateral direction of the housing of the movable unit 10 may be set in a range from 20 cm to 5 m, for example. The length of each reception electrode 220 may be set in a range from 5 cm to 2 m, for example. The width of each reception electrode 220a may be set in a range from 2 cm to 2 m, for example. The gap between two transmission electrodes, and the gap between two reception electrodes, may be set to a range from 1 mm to 40 cm, for example. However, these numerical ranges are not limiting.

FIG. 9 is a diagram showing a more specific exemplary configuration of the power transmitting circuit 110 and the power receiving circuit 210. The power transmitting circuit 110 includes an AC-DC converter circuit 140, a DC-DC converter circuit 130, a DC-AC inverter circuit 160, and a matching circuit 180. In the following description, the AC-DC converter circuit 140 may simply be referred to as the “converter 140”. The DC-DC converter circuit 130 may be referred to as the “DC-DC converter 130”. The DC-AC inverter circuit 160 may be referred to as the “inverter 160”.

The converter 140 is connected to the AC power source 20. The converter 140 converts the AC power which is output from the AC power source 20 into DC power, and outputs it. The inverter 160, which is connected to the converter 140, converts the DC power which is output from the converter 140 into an AC power of a relatively high frequency, and outputs it. The DC-DC converter 130 is a circuit that adjusts the voltage to be input to the inverter 160. In response to a command from the power transmission control circuit 150, the DC-DC converter 130 alters the voltage to be input to the inverter 160. The matching circuit 180, which is connected between the inverter 160 and the transmission electrodes 120, matches the inverter 160 and the transmission electrodes 120 in impedance. The transmission electrodes 120 send the AC power which is output from the matching circuit 180 out into space.

Through electric field coupling, the reception electrodes 220 receive at least a portion of the AC power which is sent out from the transmission electrodes 120. A matching circuit 280, which is connected between the reception electrodes 220 and a rectifier circuit 260, matches the reception electrodes 220 and the rectifier circuit 260 in impedance. The rectifier circuit 260 converts the AC power which is output from the matching circuit 280 into DC power, and outputs it. The DC power which is output from the rectifier circuit 260 is sent to the charge-discharge control circuit 290.

In the example shown in the figure, the matching circuit 180 of the power transmitting device 100 includes a series resonant circuit 180s which is connected to the inverter 160, and a parallel resonant circuit 180p which is connected to the transmission electrodes 120 and establishes inductive coupling with the series resonant circuit 180s. The series resonant circuit 180s of the power transmitter 100 includes a first coil L1 and a first capacitor C1 being connected in series. The parallel resonant circuit 180p of the power transmitter 100 includes a second coil L2 and a second capacitor C2 being connected in parallel. The first coil L1 and the second coil L2 constitute a transformer whose coupling is based on a predetermined coupling coefficient. The turns ratio between the first coil L1 and the second coil L2 is set to a value that realizes a desired step-up ratio. The matching circuit 180 steps up a voltage on the order of several ten to several hundred v which is output from the inverter 160 to a voltage on the order of several kV, for example.

The matching circuit 280 of the power receiving device 200 includes a parallel resonant circuit 280p which is connected to the reception electrodes 220 and a series resonant circuit 280s which is connected to the rectifier circuit 260 and establishes inductive coupling with the parallel resonant circuit 280p. The parallel resonant circuit 280p includes a third coil L3 and a third capacitor C3 being connected in parallel. The series resonant circuit 280s of the power receiving device 200 includes a fourth coil L4 and a fourth capacitor C4 being connected in series. The third coil L3 and the fourth coil L4 constitute a transformer whose coupling is based on a predetermined coupling coefficient. The turns ratio between the third coil L3 and the fourth coil L4 is set to a value that realizes a desired step-down ratio. The matching circuit 280 steps down a voltage on the order of several kV which is received by the reception electrodes 220 to a voltage on the order of several ten to several hundred v, for example.

Each coil in the resonant circuits 180s, 180p, 280p and 280s may be a planar coil or a laminated coil formed on a circuit board, or a wound coil in which a copper wire, a litz wire, a twisted wire or the like is used, for example. For each capacitor in the resonant circuits 180s, 180p, 280p and 280s, any type of capacitor having a chip shape or a lead shape can be used, for example. A capacitance between two wiring lines with air interposed between them may be allowed to function as each capacitor. The self-resonance characteristics that each coil possesses may be utilized in the place of any such capacitor.

The resonant frequency f0 of the resonant circuits 180s, 180p, 280p and 280s is typically set to be equal to the transmission frequency f1 during power transmission. It is not necessary for the resonant frequency f0 of each of the resonant circuits 180s, 180p, 280p and 280s to be exactly equal to the transmission frequency f1. The resonant frequency f0 of each may be set to a value in the range of about 50 to about 150% of the transmission frequency f1, for example. The frequency f1 of the power transmission may be e.g. 50 Hz to 300 GHz; 20 kHz to 10 GHz in one example; 20 kHz to 20 MHz in another example; and 80 kHz to 14 MHz in still another example.

In the present embodiment, what exists between the transmission electrodes 120 and the reception electrodes 220 is an air gap, with a relatively long distance therebetween (e.g., about 10 mm). Therefore, the capacitances Cm1 and Cm2 between the electrodes are very small, and impedances of the transmission electrodes 120 and the reception electrodes 220 are very high (e.g., on the order of several kΩ). On the other hand, the impedances of the inverter 160 and the rectifier circuit 260 are as low as about several Ω. In the present embodiment, the parallel resonant circuits 180p and 280p are disposed so as to be closer to, respectively, the transmission electrodes 120 and the reception electrodes 220; and the series resonant circuits 180s and 280s are disposed closer to, respectively, the inverter 160 and the rectifier circuit 260. Such configuration facilitates impedance matching. A series resonant circuit has zero (0) impedance during resonance, and therefore is suitable for matching with a low impedance. On the other hand, a parallel resonant circuit has an infinitely large impedance during resonance, and therefore is suitable for matching with a high impedance. Thus, as in the configuration shown in FIG. 9, disposing a series resonant circuit on the circuit with low impedance and disposing a parallel resonant circuit on the electrode with high impedance facilitates impedance matching.

Without being limited to the above configurations, any arbitrary circuit configuration may be appropriately selected for the matching circuit 260 and the matching circuit 280 so long as it enables achieving impedance matching. In configurations where the distance between the transmission electrodes 120 and the reception electrodes 220 is shortened, or a dielectric is disposed therebetween, for example, the electrode impedance will be so low that an asymmetric resonant circuit configuration is not needed. In the absence of impedance matching issues, one or both of the matching circuits 180 and 280 may be omitted. In the case of omitting the matching circuit 180, the inverter 160 and the transmission electrodes 120 are directly connected. In the case of omitting the matching circuit 280, the rectifier circuit 260 and the reception electrodes 220 are directly connected. In the present specification, a configuration where the matching circuit 180 is provided also qualifies as a configuration in which the inverter 160 and the transmission electrodes 120 are connected. Similarly, a configuration where the matching circuit 280 is provided also qualifies as a configuration in which the rectifier circuit 260 and the reception electrodes 220 are connected.

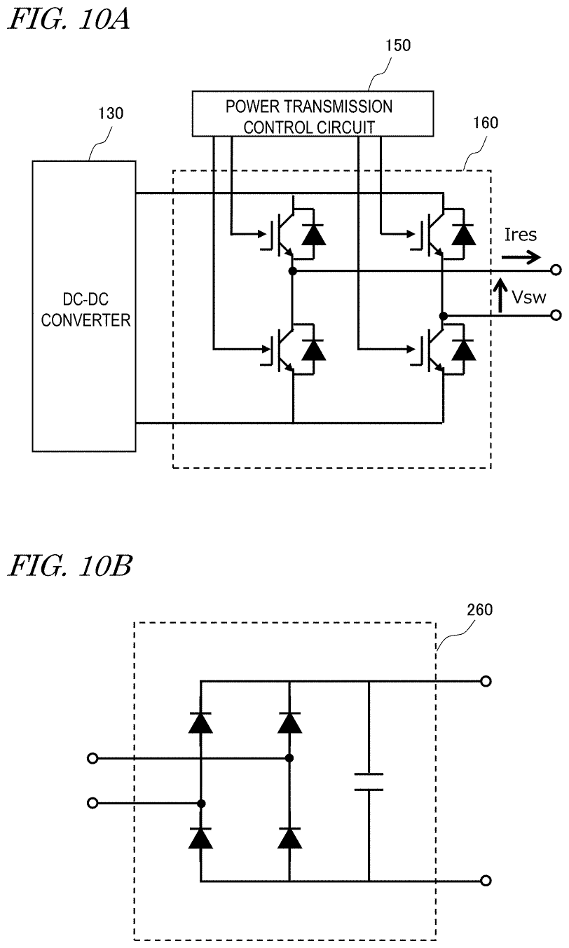

FIG. 10A is a diagram schematically showing an exemplary configuration for the inverter 160. In this example, the inverter 160 is a full-bridge inverter circuit that includes four switching elements and the power transmission control circuit 150. Each switching element may be a transistor switch such as an IGBT, a MOSFET, or a GaN-FET. The power transmission control circuit 150 includes a gate driver which outputs a control signal to control the ON (conducting) or OFF (non-conducting) state of each switching element and a microcontroller unit (MCU) which causes the gate driver to output a control signal. Instead of the full-bridge inverter that is shown in the figure, a half-bridge inverter, or any other oscillation circuit, e.g., that of class E, may also be used.

As shown in FIG. 10A, the current and voltage output from the inverter 160 are designated as Ires and Vsw, respectively. The current Ires and the voltage Vsw are detected by the detector 190 shown in FIG. 8. While a power transmission operation is being performed, the detector 190 detects the phase or timing of inversion of each of the current Ires and the voltage Vsw for every certain period of time, for example. FIG. 10B is a diagram schematically showing an exemplary configuration for the rectifier circuit 260. In this example, the rectifier circuit 260 is a full-wave rectifier circuit including a diode bridge and a smoothing capacitor. The rectifier circuit 260 may have any other rectifier configuration. The rectifier circuit 260 converts the received AC energy into DC energy which is available for use by the load, such as the battery 320.

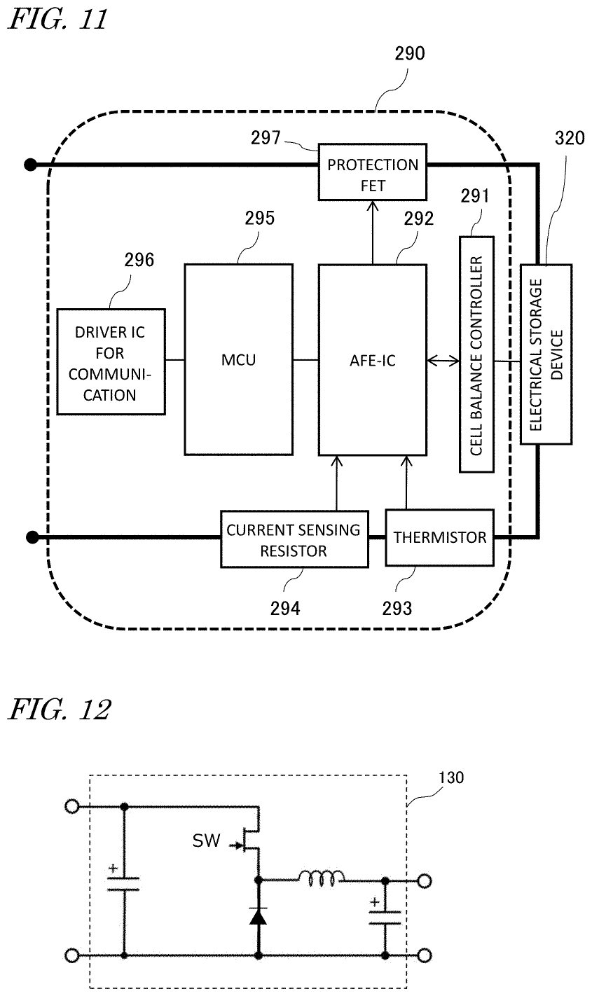

FIG. 11 is a diagram showing an exemplary configuration for the charge-discharge control circuit 290 and the impedance adjustment circuit 270. In this example, the electrical storage device 320 is a secondary battery including a plurality of cells. The charge-discharge control circuit 290 in this example includes a cell balance controller 291, an analog front-end IC (AFE-IC) 292, a thermistor 293, a current sensing resistor 294, an MCU 295, a driver IC 296 for communication purposes, and a protection FET 297. The cell balance controller 291 is a circuit which equalizes the stored electric energies in the respective cells of the secondary battery 320 that includes a plurality of cells. The AFE-IC 292 is a circuit which controls the cell balance controller 291 and the protection FET 297 based on a cell temperature measured by the thermistor 293 and a current detected by the current sensing resistor 294. The MCU 295 is a circuit which controls communications with other circuits via the driver IC 296 for communication purposes. Note that the configuration shown in FIG. 11 is only an example; depending on the required functions or characteristics, the circuit configuration may be changed.

FIG. 12 is a diagram showing one example of the circuit configuration of the DC-DC converter 130. The DC-DC converter 130 in this example is a step-down converter (buck converter) that includes a switching element SW, a diode, two capacitors, and a choke coil. Through duty control of the switching element SW, it is possible to adjust the step-down ratio. The DC-DC converter 130 may have a different circuit configuration from that of FIG. 12. The DC-DC converter 130 serves as an adjustment circuit to ensure that the electric power during the preliminary power transmission is smaller than the electric power during the main power transmission. As the power transmission control circuit 150 adjusts the duty ratio of a control signal to be input to the switching element SW of the DC-DC converter 130, i.e., the ON time ratio, the voltage to be output from the DC-DC converter 130 is adjusted. As a result, the voltage to be input to the inverter 160 is adjusted so as to be smaller during the preliminary power transmission than during the main power transmission.

Instead of the non-isolated DC-DC converter 130 shown in FIG. 12, an isolated DC-DC converter may be used. An isolated DC-DC converter is able to cause a significant step-down with a relatively high efficiency. On the other hand, a non-isolated DC-DC converter is able to finely adjust the output voltage through duty ratio adjustments. Depending on the use or purposes, an appropriate type of DC-DC converter may be selected. An isolated DC-DC converter and a non-isolated DC-DC converter may be together used while being connected in series. In the case where the voltage to be input to the inverter 160 significantly differs between the preliminary power transmission and the main power transmission, a DC-DC converter for the preliminary power transmission and a DC-DC converter for the main power transmission may be placed in parallel, and their operation may be switched depending on the power transmission mode. For example, in the case where such DC-DC converters are composed of isolated DC-DC converters, the windings of the isolation transformer have different turns ratios between the DC-DC converter for the preliminary power transmission and the DC-DC converter for the main power transmission.

Instead of the DC-DC converter 130, the AC-DC converter 140 may be configured so as to be able to adjust the output DC voltage. In that case, the DC-DC converter 130 may be omitted.

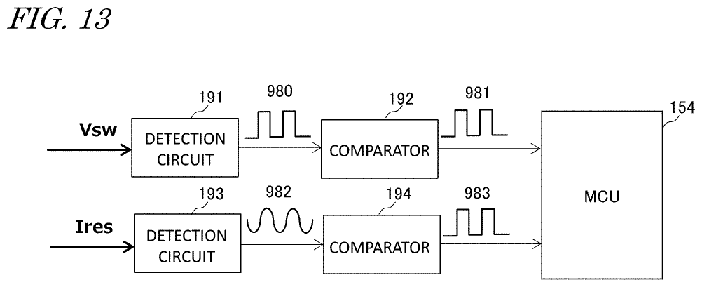

FIG. 13 is a diagram showing an exemplary configuration of the detector 190 and the power transmission control circuit 150. The detector 190 in this example includes: a detection circuit 191 that detects the output voltage Vsw and converts it to a voltage signal, which is a small signal; a comparator 192 for voltage phase detection purposes; a detection circuit 193 that detects the output current Ires and converts it to a voltage signal, which is a small signal; and a comparator 194 for current phase detection purposes. The power transmission control circuit 150 includes an MCU 154. With voltage divider resistors, the detection circuit 190 converts the output voltage Vsw of the inverter 160 to a small voltage signal 980. Then, at the timing of inversion of the voltage signal 980 being output from the detection circuit 190, the comparator 192 gives an output that switches between High and Low. As a result, voltage pulses 981 are obtained that switch between High and Low at the timing of inversion of the output voltage Vsw. Moreover, the detection circuit 193 includes a sensor element and a peripheral circuit, and converts the output current Ires of the inverter 160 into a small voltage signal 982 for output. As the sensor element, a Hall generator or a resistor for current detection purposes may be used, for example. As the peripheral circuit, for example, a differential amplification circuit may be added as necessary. The comparator 194 detects the positive or negative polarity of the voltage signal 982 which is output from the detection circuit 193, and gives an output that switches between High and Low. As a result, voltage pulses 983 are obtained that switch between High and Low at the timing of inversion of the output current Ires. The voltage pulses 981 and 983 are input to the MCU 154. The MCU 154 detects edges of the voltage pulses 981 output from the comparator 192 and the voltage pulses 983 output from the comparator 194, thereby detecting their respective phases and calculating a phase difference between the two. Note that the aforementioned detection method for phase differences is one example. For example, instead of the output voltage Vsw, a gate driving signal of a switching element in the inverter 160 that has a similar waveform and phase may be used, and compared against the phase of the output current Ires. As has been described with reference to FIG. 5, the phase difference is defined so as to take a positive value when the phase of the output current Ires is lagged behind the phase of the output voltage Vsw.

Next, an operation of the power transmitting device 100 according to the present embodiment will be described.

The power transmitting device 100 has the function of detecting whether or not the movable unit 10 has arrived at a position where power can be received from the power transmitting device 100. For example, the approaching of the movable unit 10 can be detected based on a signal that is sent from a sensor or an external managing device. When the movable unit 10 has arrived at a position where power can be received, the power transmitting device 100 performs preliminary power transmissions at a plurality of frequencies, and determines an optimum frequency. Thereafter, the power transmitting device 100 performs a main power transmission at the determined frequency.

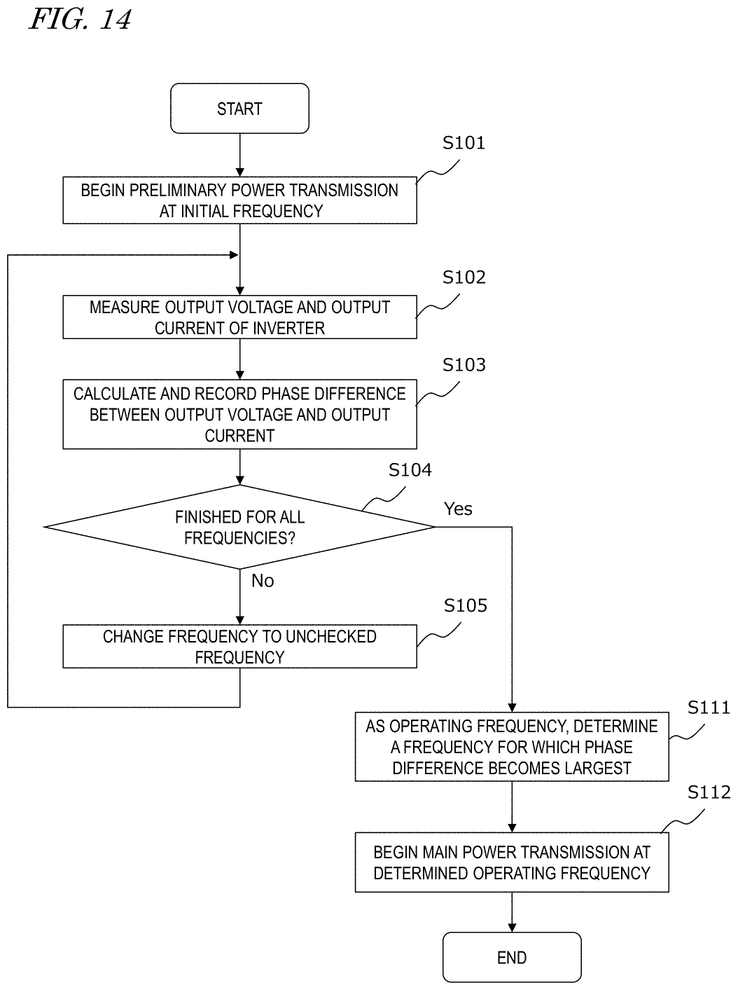

FIG. 14 is a flowchart showing an example operation by the power transmitting device 100, from the start of preliminary power transmission until the start of main power transmission. In this example, first, the power transmission control circuit 150 begins preliminary power transmission at a pre-designated initial frequency (step S101). Specifically, the power transmission control circuit 150 drives the DC-DC converter 130 in a preliminary power transmission mode, and drives each switching element in the inverter 160 at the initial frequency. Herein, the preliminary power transmission mode is a mode in which a lower voltage than that during the main power transmission is output from the DC-DC converter 130. The power transmission control circuit 150 ensures that the duty ratio of a control signal to be input to the switching element of the DC-DC converter 130, i.e., the ON time ratio, is smaller than the duty ratio during the main power transmission, thereby lowering the voltage to be input to the inverter 160. Under the preliminary power transmission mode, a voltage as low as e.g. 1/20 to ⅓ of that under the main power transmission mode is input to the inverter 160. Thus, by performing the preliminary power transmission with low electric power, the risk of heating and damaging from circuit elements associated with an impedance mismatch or hard switching during the preliminary power transmission can be reduced. However, if the risk of heating and damaging of circuit elements is small, the voltage under the preliminary power transmission mode may be made equal to the voltage under the main power transmission mode. Performing the operation under both modes with the same voltage allows the voltage switching step to be eliminated, thereby simplifying the control.

During the preliminary power transmission, the detector 190 measures the output voltage Vsw and the output current Ires of the inverter 160 (step S102). The power transmission control circuit 150 calculates a phase difference between the measured output voltage Vsw and output current Ires, and records the frequency and the phase difference, as associated with each other, in a storage medium (e.g. memory)(step S103). Herein, as described earlier, the phase difference is defined so as to take a positive value when the output current Ires is lagged behind the output voltage Vsw. Next, the power transmission control circuit 150 determines whether or not the phase difference calculation has been finished for all frequencies (step S104). If it is determined No, the power transmission control circuit 150 changes the frequency to another frequency which has not been checked for the phase difference calculation, and continues preliminary power transmission (step S105). The change of frequency is made by changing the switching frequency of each switching element in the inverter 160. When the lowest or the highest frequency in the pre-designated frequency range is set as the initial frequency, frequency may be changed by adding or subtracting a small constant amount thereto or therefrom at step S105.

The operation from step S102 to S105 is repeated until it is determined Yes at step S104. If it is determined Yes at step S104, among the plurality of frequencies for which a phase difference has been calculated, the power transmission control circuit 150 determines a frequency for which the phase difference becomes largest as the frequency to be used during the main power transmission (step S111). The power transmission control circuit 150 begins main power transmission at the determined frequency (step S112). At this time, the power transmission control circuit 150 changes the duty ratio of the control signal to be input to the switching element of the DC-DC converter 130 to the duty ratio for the main power transmission. Then, it changes the switching frequency of the inverter 160 to the determined operating frequency, and performs main power transmission.

Through the above operation, among the pre-designated plurality of frequencies, it is possible to determine the frequency that allows power transmission to be performed with the highest efficiency, and then perform main power transmission. By performing such preliminary power transmissions prior to beginning the main power transmission, degradation of the transmission efficiency can be suppressed even if the capacitance between the electrodes or the load state may possibly differ for each power transmission.

The number of frequencies to be set for preliminary power transmissions may be any number which is two or greater. The greater the number of frequencies a phase difference is calculated for, the higher the possibility of being able to set the operating frequency to a more appropriate value will be, but the longer the time required before beginning the main power transmission will be. The number of frequencies to be set for preliminary power transmissions is determined depending on the permissible delay time before the main power transmission is begun. For example, in the case where the permissible delay time is 100 milliseconds, a number of frequencies that allows the operating frequency to be determined in a shorter time than 100 milliseconds is chosen. In the case where the permissible time is about 30 milliseconds, if the amount of time required for the phase difference calculation for one frequency is about 10 milliseconds, then a phase difference may be calculated for only three frequencies, and an optimum frequency may be determined among them.

The plurality of frequencies to be used during the preliminary power transmission can be determined by various methods. For example, a reference frequency may be previously chosen to be a frequency at which the phase difference has its peak when the value of a load that is connected to the power receiving circuit 210 matches the design value (e.g., about 485 kHz in the example of FIG. 7A); then, the reference frequency, one or more frequencies lower than the reference frequency, and one or more frequencies higher than the reference frequency may be chosen as the frequencies to be used during the preliminary power transmission. The frequency intervals between the plurality of frequencies to be used during the preliminary power transmission do not need to be equal. For example, the plurality of frequencies may chosen such that the intervals between frequencies farther away from the reference frequency are wider. The operation of determining the optimum frequency may be performed not only prior to beginning the main power transmission, but also during the main power transmission. In particular, in the case where the main power transmission takes a long time, there is a high possibility that the coupling state between the antennas or the load state may vary during the main power transmission, thus illustrating the advantage of introducing the operation of changing to a more suitable frequency during the power transmission.

In the example of FIG. 14, a phase difference is calculated for all of the pre-designated plurality of frequencies, and the frequency at which the phase difference becomes largest is determined as the operating frequency during the main power transmission. Without being limited to such an operation, the operating frequency may be determined by other methods. For example, a frequency at which the phase difference becomes maximal may be searched for by the hill-climbing method, and this frequency may be determined as the operating frequency.

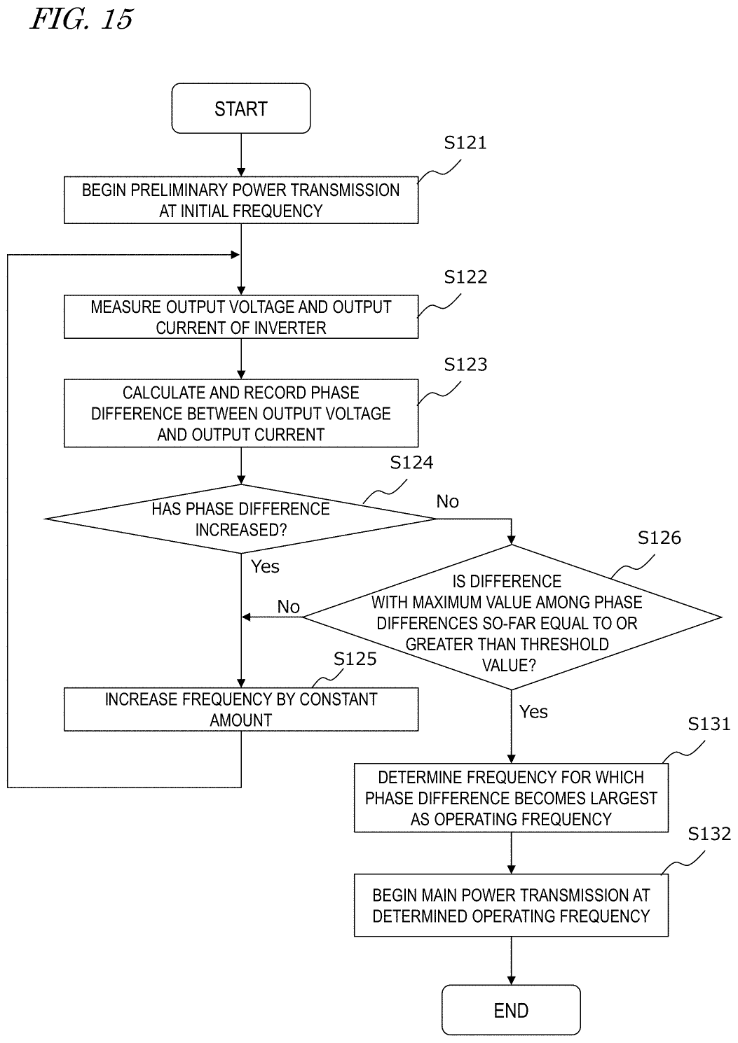

FIG. 15 is a flowchart showing an example operation where a frequency at which the phase difference becomes maximal is determined by the hill-climbing method. In this example, first, the power transmission control circuit 150 begins preliminary power transmission at an initial frequency (step S121). The initial frequency in this example is the lowest frequency among the pre-designated plurality of frequencies. Similarly to the earlier example, the detector 190 measures the output voltage and the output current of the inverter (step S122). The power transmission control circuit 150 calculates a phase difference indicating a lag of the output current relative to the measured output voltage, and records this frequency and this phase difference, as associated with each other, in a storage medium (step S123). Next, the power transmission control circuit 150 determines whether the calculated phase difference has increased from the previous phase difference (which, at the initial time, has a sufficiently large negative value) or not (step S124). If it is determined Yes at step S124, the power transmission control circuit 150 increases the frequency by a constant amount (step S125), and returns to step S122. If it is determined No at step S124, the power transmission control circuit 150 determines whether or not a difference between the currently-calculated phase difference and a maximum value among the phase differences so-far calculated is equal to or greater than a threshold value (step S126). This step is performed in order to prevent a phase difference that is actually not maximal from being erroneously determined as maximal due to noise or other causes. The threshold value is previously set to an appropriate value that is sufficiently larger than fluctuations of the signal due to noise. If it is determined No at step S126, control proceeds to step S125, where the frequency is increased by the constant amount, and the preliminary power transmission is continued. If it is determined Yes at step S126, from among the frequencies for which a phase difference has been calculated so far, the power transmission control circuit 150 determines the frequency for which the phase difference becomes largest as the operating frequency (step S131). Then, the power transmission control circuit 150 begins main power transmission at the determined operating frequency (step S132).

With the operation of FIG. 15, the preliminary power transmissions are ended as soon as identifying the frequency at which the phase difference becomes maximal; and this is then followed by the main power transmission. Therefore, it is possible to begin the main power transmission in a relatively short time.

In the example of FIG. 15, the initial frequency is set to the lowest frequency within a pre-designated frequency range; however, it may be set to the highest frequency within the frequency range. In that case, at step S125, the power transmission control circuit 150 performs an operation of decreasing the frequency by a constant amount. Note that, at step S125, rather than changing the frequency by a constant amount, the amount of change in frequency may be altered in accordance with its difference with the pre-designated reference frequency. For example, the reference frequency may be chosen to be a frequency that results in a highest efficiency when the capacitance between the electrodes and the load value are identical to their design values; the amount of change in frequency may be monotonically decreased as it gets closer to the reference frequency; and the amount of change in frequency may be monotonically increased as it gets farther away from the reference frequency.

The operations illustrated in FIG. 14 and FIG. 15 are only exemplary, which, in actual applications, are open to appropriate modifications. In the present embodiment, the detector 190 detects a voltage and a current between the inverter 160 and the matching circuit 180. Without being limited thereto, the detector 190 may detect a voltage and a current inside the matching circuit 180. For example, a voltage and a current at a point before undergoing a step-up in the matching circuit 180 shown in FIG. 9 may be detected.

The operating frequency during the main power transmission may not be the frequency at which the phase difference becomes largest among the plurality of frequencies for which a phase difference has been measured. So long as the action and effects in the present embodiment are obtained, any frequency that is different from the above-described frequency may be set as the operating frequency.

Although the pair of transmission electrodes 120 are installed on the ground in the above embodiments, the pair of transmission electrodes 120 may instead be installed on a lateral surface, e.g., a wall, or an overhead surface, e.g., a ceiling. Depending on the place and orientation in which the transmission electrodes 120 are installed, the arrangement and orientation of the reception electrodes 220 of the movable unit 10 are to be determined.

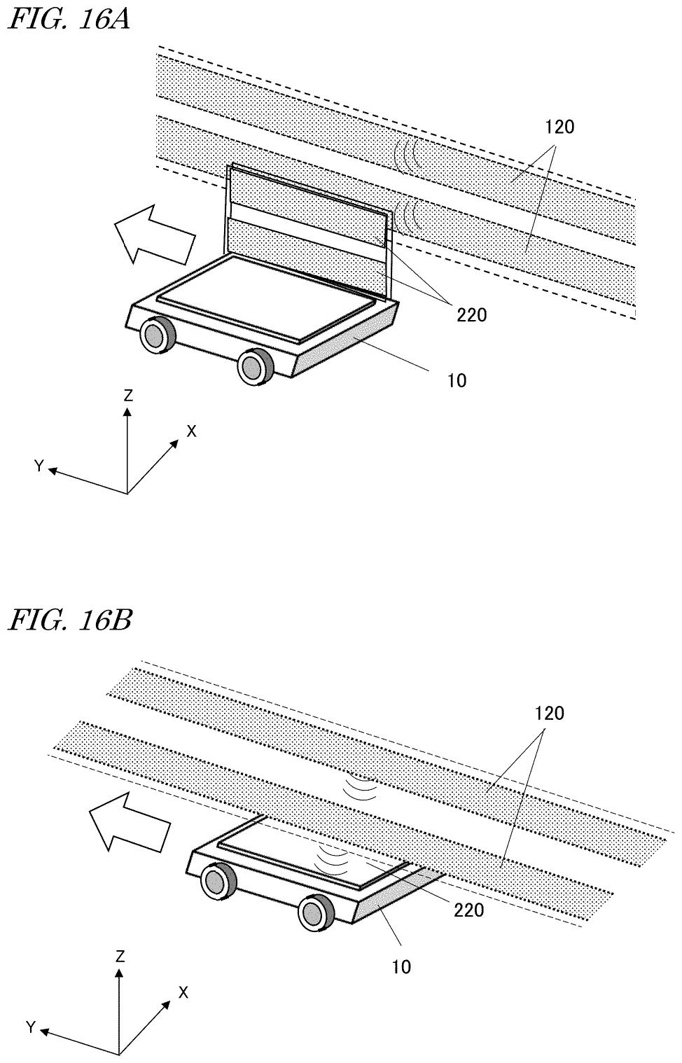

FIG. 16A shows an example where the transmission electrodes 120 are installed on a lateral surface e.g., a wall. In this example, the reception electrodes 220 are provided on a lateral side of the movable unit 10. FIG. 16B shows an example where the transmission electrodes 120 are installed on a ceiling. In this example, the reception electrodes 220 are provided on the top of the movable unit 10. As demonstrated by these examples, there may be a variety of arrangements for the transmission electrodes 120 and the reception electrodes 220.

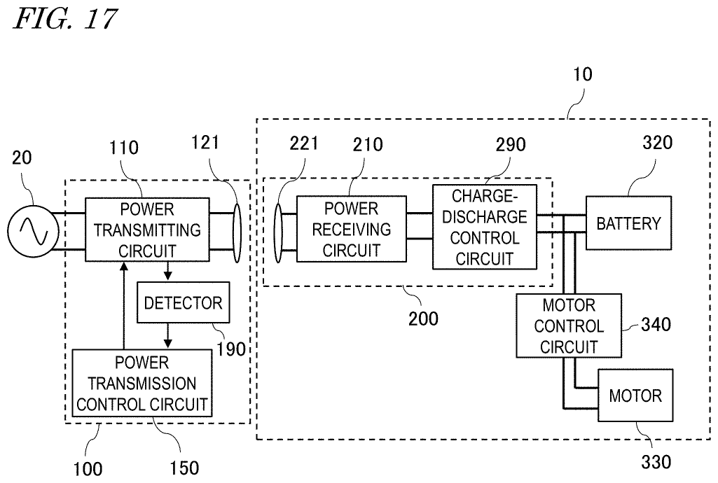

FIG. 17 is a diagram showing an exemplary configuration of a system in which electric power is wirelessly transmitted through magnetic field coupling between coils. In this example, a power transmitting coil 121 is provided instead of the transmission electrodes 120 shown in FIG. 8, and a power receiving coil 122 is provided instead of the reception electrodes 220. While the power receiving coil 122 is opposed to the power transmitting coil 121, electric power is wirelessly transmitted from the power transmitting coil 121 to the power receiving coil 221. With such a configuration, too, effects similar to those of the above embodiments can be obtained.

A wireless power transmission system according to an embodiment of the present disclosure may be used as a system of transportation for articles within a factory, as mentioned above. The movable unit 10 functions as a cart having a bed on which to carry articles, and autonomously move in the factory to transport articles to necessary places. However, without being limited to such purposes, the wireless power transmission system and the movable unit according to the present disclosure are also usable for various other purposes. For example, without being limited to an AGV, the movable unit may be any other industrial machine, a service robot, an electric vehicle, a multicopter (so-called a drone), or the like. Without being limited to being used in a factory, the wireless power transmission system may be used in shops, hospitals, households, roads, runways, or other places, for example.

### INDUSTRIAL APPLICABILITY

The technique according to the present disclosure is applicable to any device that is driven with electric power. For example, it is suitably applicable to electric vehicles, such as automated guided vehicles (AGV).

### REFERENCE SIGNS LIST

10 movable unit
20 power source
30 floor surface
100 power transmitting device
110 power transmitting circuit
120, 120a, 120b transmission electrode
130 DC-DC converter circuit
140 AC-DC converter circuit
150 power transmission control circuit
160 DC-AC inverter circuit
180 matching circuit
180s series resonant circuit
180p parallel resonant circuit
190 detector
200 power receiving device
210 power receiving circuit
220, 220a, 220b reception electrode
260 rectifier circuit
280 matching circuit
280p parallel resonant circuit
280s series resonant circuit
290 charge-discharge control circuit
310 electrical storage device
320 secondary battery
330 electric motor
340 motor control circuit

1. A power transmitting device for use in a wireless power transmission system that includes the power transmitting device and a power receiving device, the power transmitting device comprising:
an inverter circuit;
a power transmitting antenna connected to the inverter circuit, and being electromagnetically coupled to a power receiving antenna in the power receiving device to wirelessly transmit electric power thereto;
a detector to detect an output voltage and an output current of the inverter circuit; and
a control circuit to control the inverter circuit, the control circuit consecutively driving the inverter circuit at a plurality of frequencies, determining from among the plurality of frequencies a frequency at which a phase difference that is indicative of a lag of a phase of the output current relative to a phase of the output voltage becomes largest, and performing power transmission by driving the inverter circuit at an operating frequency that is based on the determined frequency.

2. The power transmitting device of claim 1, further comprising an adjustment circuit to adjust a voltage to be input to the inverter circuit, wherein
the control circuit controls the adjustment circuit to perform an operation of determining the operating frequency with an electric power which is lower than that in a power transmission operation occurring after the operating frequency has been determined.

3. The power transmitting device of claim 1, wherein the adjustment circuit is a DC-DC converter circuit connected between an external DC power source and the inverter circuit, or an AC-DC converter circuit connected between an external AC power source and the inverter circuit.

4. The power transmitting device of claim 1, wherein the plurality of frequencies comprise three or more frequencies.

5. The power transmitting device of claim 1, wherein the control circuit uses the hill-climbing method to determine the frequency at which the phase difference becomes largest.

6. The power transmitting device of claim 1, wherein the control circuit performs the operation of determining the operating frequency in an amount of time shorter than 1 second.

7. The power transmitting device of claim 1, further comprising an impedance matching circuit connected between the inverter circuit and the power transmitting antenna, wherein
the detector detects a voltage and a current between the inverter circuit and the impedance matching circuit, or inside the impedance matching circuit, respectively as the output voltage and the output current.

8. The power transmitting device of claim 1, wherein,
the power receiving antenna includes two or more reception electrodes; and
the power transmitting antenna includes two or more transmission electrodes for electric field coupling with the two or more reception electrodes.

9. A wireless power transmission system comprising:
the power transmitting device of claim 1; and
the power receiving device.

10. The wireless power transmission system of claim 9, comprising a movable unit that includes the power receiving device.
